(19) United States
(12) Patent Application Publication
(10) Pub. No.: US 2011/0267795 A1
(43) Pub. Date: Nov. 3, 2011

(54) ELECTRONIC PASSPORT CASE FOR PREVENTING LEAKAGE OF INFORMATION AND IMPROVING RECOGNITION RATE

(75) Inventors: Sun Hoo Kim, Gyeonggi-do (KR); Young Deug Ko, Gyeonggi-do (KR); Si Pyo Hong, Gyeonggi-do (KR); Hyung Chun Lee, Gyeonggi-do (KR)

(73) Assignee: DOOSUNG INDUSTRIAL CO., LTD., Kyunggi-Do (KR)

(21) Appl. No.: 13/143,022

(22) PCT Filed: Sep. 15, 2009
(86) PCT No.: PCT/KR2009/005242

§ 371 Date: Jun. 30, 2011

(30) Foreign Application Priority Data
Dec. 30, 2008 (KR) 10-2008-0136716

(51) Int. Cl. H05K 9/00

(52) U.S. Cl. 361/818

(57) ABSTRACT

The present invention relates to an electronic passport case for preventing a leakage of information and improving a recognition rate. More particularly, the present invention relates to an electronic passport case that prevents a leakage of information by shielding electromagnetic waves which reach an electronic chip and improves a recognition rate of the electronic chip incorporated in the electronic passport in order to prevent personal information of an electronic passport owner stored in the electronic chip incorporated in the electronic passport from being leaked arbitrarily unintentionally. The present invention provides an electronic passport case for preventing a leakage of information and improving a recognition rate, including an electromagnetic wave shielding layer formed to cover an electronic passport and preventing an electronic wave from reaching an electronic chip incorporated in the electronic passport. According to the present invention, it is possible to prevent biological information and personal information of an electronic passport owner recorded in an electronic chip of an electronic passport from being arbitrarily leaked and misused, and to perform communication between the electronic chip and a recognizer stably.

### TECHNICAL FIELD

The present invention relates to an electronic passport case for preventing a leakage of information and improving a recognition rate. More particularly, the present invention relates to an electronic passport case that prevents a leakage of information by shielding electromagnetic waves which reach an electronic chip incorporated in the electronic passport and improves recognition rate of the electronic chip, in order to prevent personal information of the electronic passport owner stored in the electronic chip incorporated in the electronic passport from being leaked unintentionally arbitrarily.

### BACKGROUND

In general, since a radio frequency identification (RFID) system as a system that can transmit and receive various data through a wireless type by using a predetermined frequency band can automatically recognize an object and perform authentication of the object and settlement, the system has come into the spotlight.

The RFID system is constituted by an electronic chip incorporated in or attached to a recognition object and a recognizer recognizing information of the electronic chip outside the system and as a passport, an electronic passport incorporating the electronic chip has been used recently.

The electronic passport includes biological information such as a fingerprint of the electronic passport owner, and the like and more conveniently, enables entry and departure procedures and can easily distinguish counterfeiting or not by comparing the contents of the electronic chip with identification information during an entry and departure checking procedure.

However, since the electronic passport uses a contactless electronic chip in terms of a characteristic, information associated with the electronic passport owner can be leaked merely by making the recognizer capable of recognizing the electronic chip incorporated in the electronic passport close to the electronic passport outside.

Various encryption techniques are utilized in order to prevent information of the electronic passport from being leaked, but a hacking technology developed with an encryption technology makes up a trouble for preventing the leakage of information of the electronic passport with nothing.

Further, a propagation interference phenomenon by an electromagnetic wave shielding material used in order to prevent the information leakage influences communication between the electronic chip and the recognizer to shorten a recognition distance and deteriorate the recognition rate of the electronic chip.

Therefore, a means for preventing personal biological information recorded in the electronic chip of the electronic passport from being leaked arbitrarily needs to be provided.

### SUMMARY

In order to solve the problems, an object of the present invention is to provide an electronic passport case for preventing a leakage of information and improving a recognition rate that can prevent biological information and personal information of an electronic passport owner from being leaked arbitrarily from an electronic chip incorporated in an electronic passport and improve a recognition rate of the electronic chip, and keep the electronic passport for a long time by preventing the electronic passport from being damaged.

In order to achieve the above object, the present invention provides an electronic passport case for preventing a leakage of information and improving a recognition rate including: an electromagnetic wave shielding layer formed to cover an electronic passport and preventing an electronic wave from reaching an electronic chip incorporated in the electronic passport; and a magnetic body provided between the electromagnetic wave shielding layer and the electronic chip and made of a material having magnetism, wherein the electromagnetic wave shielding layer and the magnetic body are formed at a part where the electronic chip is positioned with a predetermined size to cover the electronic chip.

Herein, the electromagnetic wave shielding layer may be formed by a metallic foil reflecting the electromagnetic wave.

Further, the electromagnetic wave shielding layer may be formed by a material plated with metal reflecting the electromagnetic wave.

In addition, the electromagnetic wave shielding layer may include a sheet printed with a conductive ink.

Besides, the magnetic body may be formed in a sheet shape by mixing a magnetic powder with a polymer resin.

Moreover, the conductive ink may be printed on a film in a polygonal shape.

In addition, the magnetic body may be formed by mixing any one or two or more of ferrite, sendust, a permalloy, and Fe—Si—Cr based magnetic powders with any one polymer resin selected from silicon, urethane, and chlorinated polyethylene and in a sheet shape having a thickness in the range of 0.05 to 0.5 mm.

Further, the magnetic body may include a halogen free resin formed by sequentially adding and mixing polyolefin based elastomer and the sendust power and a deoxidant and a surface modifier.

Besides, the electronic passport case further may include a spacer layer forming a spacing distance between the electronic chip and the electromagnetic wave absorbing layer at between the electronic chip and the electromagnetic wave absorbing layer.

In addition, the metal plated material may be formed by sequentially laminating a first nickel plated layer, a copper plated layer, and a second nickel plated layer on the surface of a polyester material having a thickness in the range of 50 to 200 μm.

Moreover, the sheet printed with the conductive ink may be formed by printing a hexagonal pattern having a thickness in the range of 5 to 30 μm, a line width in the range of 0.05 to 0.3 mm, and a line interval in the range of 0.5 to 2.0 mm on a PET film having a thickness in the range of 20 to 200 μm by using a conductive ink including a silver (Ag) powder.

Besides, the electromagnetic wave shielding layer and the magnetic body may be coupled with each other through heat fusion.

According to exemplary embodiments of the present invention, it is possible to prevent biological information and personal information of an electronic passport owner recorded in an electronic chip of an electronic passport from being arbitrarily leaked and misused, and to perform communication between the electronic chip and a recognizer stably.

Further, it is possible to prevent the electronic passport from being damaged by containing and keeping the electronic passport.

### BRIEF DESCRIPTION OF DRAWINGS

FIG. 1 is a perspective view of an electronic passport case for preventing a leakage of information and improving a recognition rate according to an exemplary embodiment of the present invention.

FIG. 2 is a cross-sectional view showing a state in which an electronic passport is contained in an electronic passport case for preventing a leakage of information and improving a recognition rate according to an exemplary embodiment of the present invention.

FIG. 3 is a diagram showing a state in which an electronic passport is inserted into an electronic passport case for preventing a leakage of information and improving a recognition rate according to an exemplary embodiment of the present invention.

FIG. 4 is a diagram showing an exemplary embodiment of an electromagnetic wave shielding layer and a magnetic body.

FIG. 5 is a diagram showing another exemplary embodiment of an electromagnetic wave shielding layer and a magnetic body.

FIG. 6 is a graph showing an electromagnetic wave shielding effectiveness of an electronic passport case according to Example 1.

FIG. 7 is a graph showing an electromagnetic wave shielding effectiveness of an electronic passport case according to Example 2.

FIG. 8 is a graph showing an electromagnetic wave shielding effectiveness of an electronic passport case according to Example 3.

FIG. 9 is a graph showing an electromagnetic wave shielding effectiveness of an electronic passport case according to Example 4.

FIG. 10 is a diagram showing a sheet printed with a conductive ink.

FIG. 11 is a graph showing an electromagnetic wave shielding effectiveness of an electronic passport case according to Example 5.

### DETAILED DESCRIPTION

Hereinafter, exemplary embodiments of the present invention will be described in detail with reference to the accompanying drawings. First of all, it is to be noted that in giving reference numerals to elements of each drawing, like reference numerals refer to like elements even though like elements are shown in different drawings. Further, in describing the present invention, well-known functions or constructions will not be described in detail since they may unnecessarily obscure the understanding of the present invention. Hereinafter, the exemplary embodiment of the present invention will be described, but it will be understood to those skilled in the art that the spirit and scope of the present invention are not limited thereto and various modifications and changes can be made.

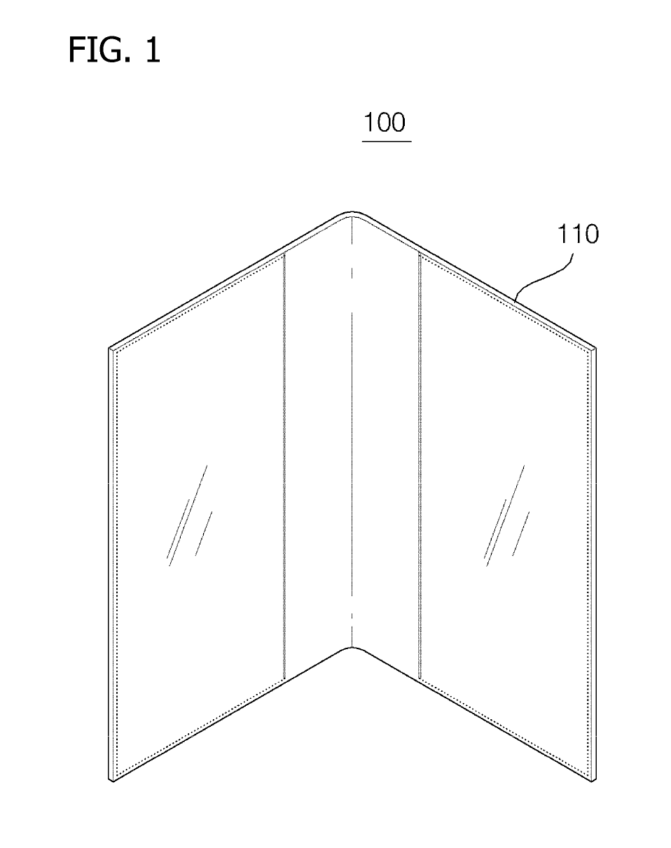

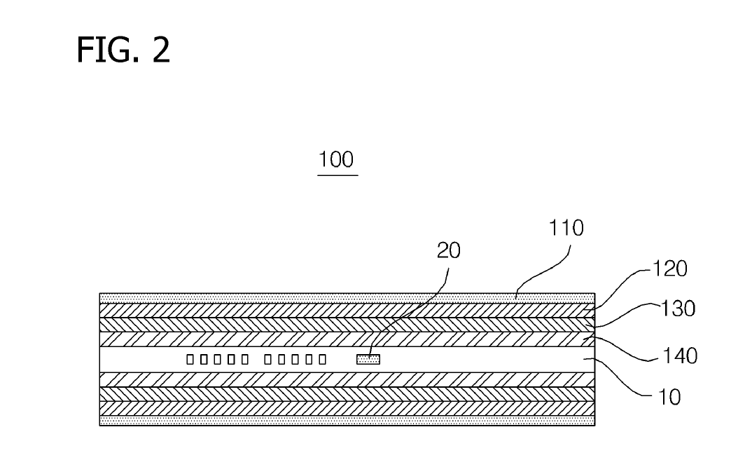

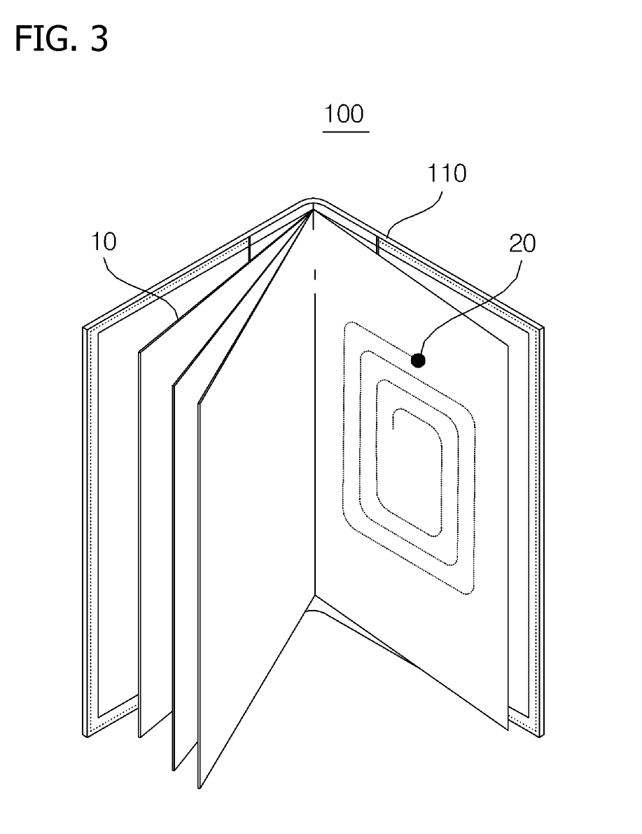

FIG. 1 is a perspective view of an electronic passport case for preventing a leakage of information and improving a recognition rate according to an exemplary embodiment of the present invention, FIG. 2 is a cross-sectional view showing a state in which an electronic passport is kept in an electronic passport case for preventing a leakage of information and improving a recognition rate according to an exemplary embodiment of the present invention, and FIG. 3 is a diagram showing a state in which an electronic passport is inserted into an electronic passport case for preventing a leakage of information and improving a recognition rate according to an exemplary embodiment of the present invention.

An electronic passport case 100 for preventing a leakage of information and improving a recognition rate according to an exemplary embodiment of the present invention contains and keeps an electronic passport 10 and has the same type as a wallet and preferably, includes a sealing portion (not shown) to cover the side of the electronic passport 10. However, the electronic passport case 100 for preventing a leakage of information and improving a recognition rate does not particularly need to have the shape of the wallet and may have any case shape to shield electromagnetic waves by containing the electronic passport 10.

Meanwhile, the electronic passport case 100 for preventing a leakage of information and improving a recognition rate according to an exemplary embodiment of the present invention includes an outer cover 110, an electromagnetic wave shielding layer 120, a magnetic body 130, and a spacer layer 140.

The outer cover 110 may be made of materials such as cloth, vinyl, leather, and the like and includes the electromagnetic wave shielding layer 120, the magnetic body 130, and the spacer layer 140 inside the outer cover 110.

The electromagnetic wave shielding layer 120 prevents electromagnetic waves from reaching an electronic chip 20 provided in the electronic passport 10 by reflecting the electromagnetic waves and may be provided inside the outer cover 110.

The electromagnetic wave shielding layer 120 may be made of a metallic foil having excellent electrical conductivity and may include any one of a nickel foil, an aluminum foil, a copper foil, a gold foil, a silver foil, and a permalloy foil.

The electromagnetic wave shielding layer 120 may be formed by using a material plated with metal. The plated material is formed by plating the surface of a fiber material having a thickness in the range of 50 to 200 μm, such as polyester, polyurethane, or acryl with a conductive metallic particle including any one of copper, nickel, tin, aluminum, gold, and silver.

In this case, when the thickness of the fiber material is less than 50 μm, there are concerns about damage of the material in manufacturing and damage of a bent portion by repetitive opening and closing, and when the thickness is more than 200 μm, the total weight and thickness of the electronic passport case 100 increase, and as a result, carrying the electronic passport case 100 becomes inconvenient and the thickness of the fiber material increases, and as a result, repetitive opening and closing become difficult.

In some cases, the electromagnetic wave shielding layer 120 may be formed by applying the above method to a film or a mesh-shaped material instead of the fiber material.

Further, the electromagnetic wave shielding layer 120 may be formed by a sheet applied with a conductive ink. Herein, the conductive ink includes any one or metallic powder mixed by two or more selected from silver, gold, platinum, palladium, copper, and nickel and the conductive ink is applied onto the surface of the sheet or film or printed with a pattern of a lattice or polygonal shape through a printing process. In this case, as the sheet to which the conductive ink is applied or printed, metal, fiber, paper, leather, rubber, and a polymer film made of polypropylene (PP) or polyethylene terephthalate (PET) may be used.

Meanwhile, the thickness of the sheet to which the conductive ink will be applied is preferably in the range of 20 to 200 μm, and when the thickness is less than 20 μm, there are concerns about damage of the sheet and damage of a bent portion by repetitive opening and closing during washing and degreasing of the sheet, and when the thickness is more than 200 μm, the total weight and thickness of the electronic passport case 100 increase, and as a result, carrying the electronic passport case 100 becomes inconvenient and the thickness of the fiber material increases, and as a result, repetitive opening and closing become difficult.

Meanwhile, the pattern printed on the sheet is preferably printed with a polygonal pattern in which the thickness of the applied conductive ink is in the range of 5 to 30 μm, and the line width is in the range of 0.05 to 0.3 mm and the line interval is in the range of 0.5 to 2.0 mm.

Herein, when the thickness of the conductive ink is less than 5 μm, electromagnetic wave shielding performance deteriorates, and when the thickness is 30 μm, sufficient electromagnetic wave shielding performance is acquired and thus, it is unnecessary to apply the conductive ink with the thickness of 30 μm or more.

Further, even when the line width is less than 0.05 mm, the electromagnetic wave shielding performance deteriorates, and when the line width is 0.3 mm, the sufficient performance is acquired and thus, it is unnecessary to form the pattern with the line width of 0.3 mm or more.

When the line interval is more than 2.0 mm, there is increased a possibility that the electromagnetic wave will penetrate a gap between lines and a line interval for shielding the electromagnetic wave is preferably 0.5 mm or more by considering that a minimum line width is 0.05 mm.

The sheet may be used after washing and degreasing or used particularly after pre-processing. The pre-processing method includes primer processing using plasma, an ion beam, corona, oxidation or deoxidization, heat, etching, ultraviolet-ray irradiation, and an additive. As the method of forming the electromagnetic wave shielding layer 120 by printing the conductive ink on the sheet, spin coating, roll coating, spray coating, dip coating, flow coating, doctor blade and dispensing, inkjet printing, offset printing, screen printing, pad printing, flexography printing, stencil printing, imprinting, xerography, lithography, and the like may be used. Further, transparency may be improved by printing the conductive ink on the sheet in the lattice shape.

The magnetic body 130 absorbs and removes electromagnetic waves generated from electrical, electronic, and communication apparatuses by magnetic loss, dielectric loss, resistive loss, and the like.

The magnetic body 130 is formed by mixing a polymer resin and magnetic powder. In other words, the magnetic body 130 may be formed in a sheet shape having a thickness in the range of 0.05 to 0.5 mm by mixing flake powders such as ferrite, sendust (Fe—Si—Al alloy), permalloy (Ni—Fe alloy), and Fe—Si—Cr based alloy with rubber resins such as silicon, urethane, and chlorinated polyethylene (CPE) and thereafter, forming the mixture by using a calendar or a hot press.

Herein, when the thickness of the sheet is less than 0.05 mm, electromagnetic wave absorbing performance deteriorates, and when the thickness is more than 0.5 mm, the total thickness and weight of the electronic passport case 100 increase, and as a result, carrying the electronic passport case 100 becomes inconvenient.

Meanwhile, a frequency of a predetermined band can be selectively absorbed by selectively using the materials or changing an addition ratio.

However, when the chlorinated polyethylene rubber is used at the time of forming the magnetic body 130, this method is not environmentally friendly. Therefore, the magnetic body 130 is more preferably formed by a polyolefin-based resin having a halogen free characteristic in respect to the environment.

The halogen free resin may be formed by sequentially adding and mixing polyolefin-based elastomer (ethylene-octen copolymer) and polyolefin-based elastomer rubber, sendust powder surface-coated with a silicon-based coupling agent, and a phenolic antioxidant and a surface modifier through measurement. When the components are kneaded and thereafter, formed by using the calendar, a thin magnetic body 130 having a predetermined thickness can be acquired.

The magnetic body 130 is disposed between the electromagnetic wave shielding layer 120 and the electronic chip 20 and heat-fused onto an inner surface of the electromagnetic wave shielding layer 120 to be integratively coupled with the electromagnetic wave shielding layer 120. Various kinds of electromagnetic wave shielding layers 120 and magnetic bodies 130 may be attached to each other through heat fusion and more effectively attached to each other.

The spacer layer 140 may be made of the same materials such as cloth, vinyl, and leather as the outer cover 110 and may serve as an inner cover protecting the electronic passport 10. The electronic chip 20 and the electromagnetic wave shielding layer 120 incorporated in the electronic passport 10 together with the magnetic body 130 are spaced apart from each other to improve the recognition rate of the electronic chip 20. Further, when the spacer layer 140 is formed by a dielectric substance, it is possible to reduce an electrical influence on the electronic chip 20.

As shown in FIG. 2, the spacer layer 140, the magnetic body 130, and the electromagnetic wave shielding layer 120 are sequentially placed in the order close to the electronic chip 20. When the electronic passport 10 is put in the electronic passport case 100 formed as above and the electronic passport case 100 is closed, the electromagnetic wave shielding layer 120 covering an exterior of the electronic passport 10 reflects the electromagnetic wave to prevent the electronic wave from reaching the electronic chip 20. Further, when the electronic passport case 100 is opened to allow the electronic chip 20 to be recognized by the recognizer, the recognition rate of the electronic chip 20 by the recognizer can be improved by the magnetic body 130 between the electromagnetic wave shielding layer 120 and the electronic chip 20.

The reason for improving the recognition rate as described above is that the magnetic body 130 focuses the electromagnetic wave transferred from the recognizer on the electronic chip 20 of the electronic passport 10, the magnetic powder having high permeability used in the magnetic body 130 increases inductance of the electronic chip 20, and a high voltage is induced to the electronic chip 20 to increase a recognition distance of the electronic chip 20, at the time of recognizing the electronic chip 20 incorporated in the electronic passport 10 through the recognizer by opening the electronic passport case 100.

Meanwhile, the recognition distance in which the recognizer can recognize the electronic chip 20 is maintained at an appropriate level only when the electronic chip 20 and the electromagnetic wave shielding layer 120 placed as described above are spaced apart from each other by a predetermined distance, and the spacing distance can be maintained by the magnetic body 130 and the spacer layer 140.

The electromagnetic wave shielding layer 120, the magnetic body 130, and the spacer layer 140 included in the electronic passport case 100 for preventing a leakage of information and improving a recognition rate according to the exemplary embodiment of the present invention may be formed on a full surface of the electronic passport case 100 for preventing a leakage of information and improving a recognition rate so as to fully cover the electronic passport 10 or at only a part of the electronic passport case 100 for preventing a leakage of information and improving a recognition rate so as to cover only a part where the electronic chip 20 incorporated in the electronic passport 10 is placed.

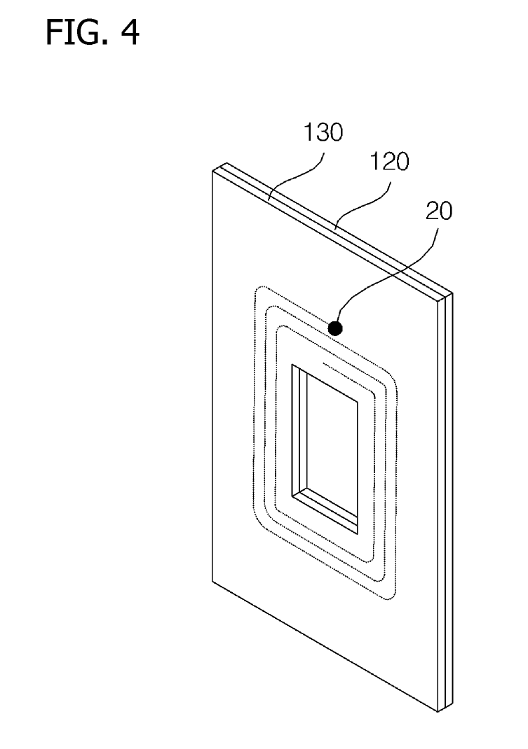

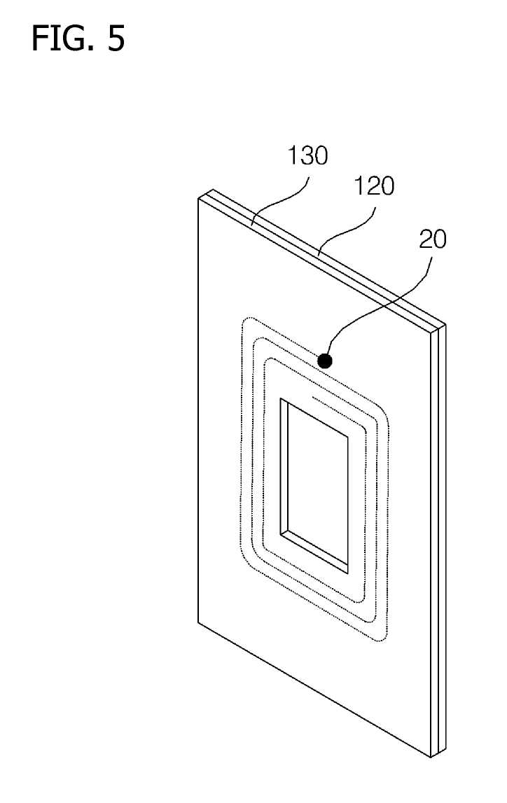

Further, for implementing light weight of the electronic passport case 100 for preventing a leakage of information and improving a recognition rate, a part of each of the electromagnetic wave shielding layer 120 and the magnetic body 130 which does not correspond to parts where the electronic chip 20 and an antenna are positioned may be removed as shown in FIG. 4 or only the part of the magnetic body 130 which does not correspond to the part where the electronic chip 20 and the antenna are positioned may be removed as shown in FIG. 5.

Hereinafter, the present invention will be described in more detail through examples of the electronic passport case 100 for preventing a leakage of information and improving a recognition rate.

First, as described in examples 1 to 5 below, the electronic passport case 100 was formed and thereafter, electromagnetic wave shielding effectiveness and a skimming prevention rate of the electronic passport case 100 manufactured according to each example were measured.

As a method of measuring the electromagnetic wave shielding effectiveness, standards of ASTM D-4935 and KS C0304 are used. This is applied to measure a shielding effect of a planar material under the condition that a planar wave is vertically incident in a sample within a far field and is the method of measuring the shielding effect generated by reflection and absorption by the material. The electromagnetic wave shielding effectiveness is expressed by a ratio of energy permeabilities of the sample and a reference sample and the unit thereof is expressed as a decibel (dB).

The skimming prevention rate, as a numerical value acquired by converting the electromagnetic wave shielding effectiveness expressed as dB into %, represents efficiency in which the electromagnetic wave was actually shielded. As a measurement device, an Agilent CSA Spectrum analyzer made by Agilent Technologies was used.

### Example 1

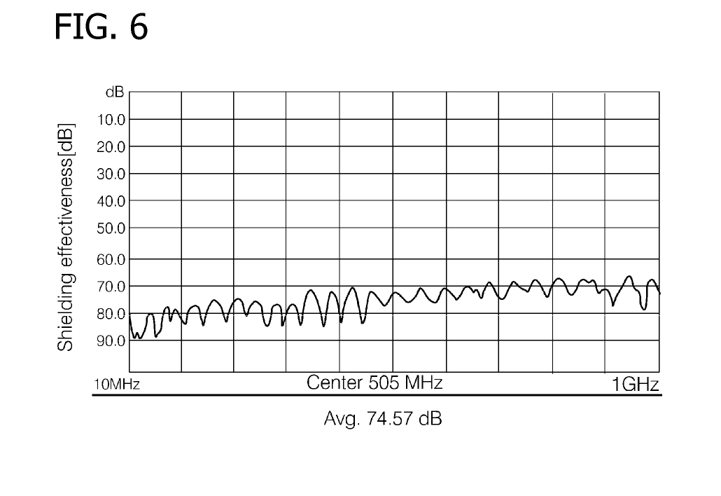

The electronic passport case 100 using an aluminum foil having a thickness of 70 μm as the electromagnetic wave shielding layer 120 was manufactured, and the electromagnetic wave shielding effectiveness and skimming prevention rate for the manufactured electronic passport case 100 were measured. A graph of a measurement result of the electromagnetic wave shielding effectiveness therefor is shown in FIG. 6.

### Example 2

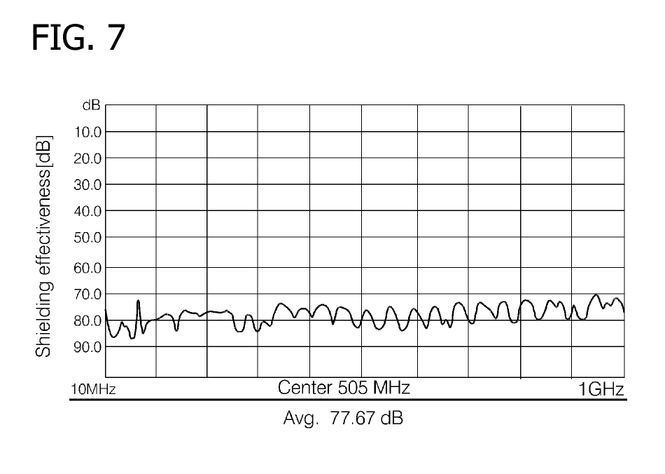

The electronic passport case 100 using a copper foil having a thickness of 70 μm as the electromagnetic wave shielding layer 120 was manufactured, and the electromagnetic wave shielding effectiveness and skimming prevention rate for the manufactured electronic passport case 100 were measured. A graph of a measurement result of the electromagnetic wave shielding effectiveness therefor was shown in FIG. 7.

### Example 3

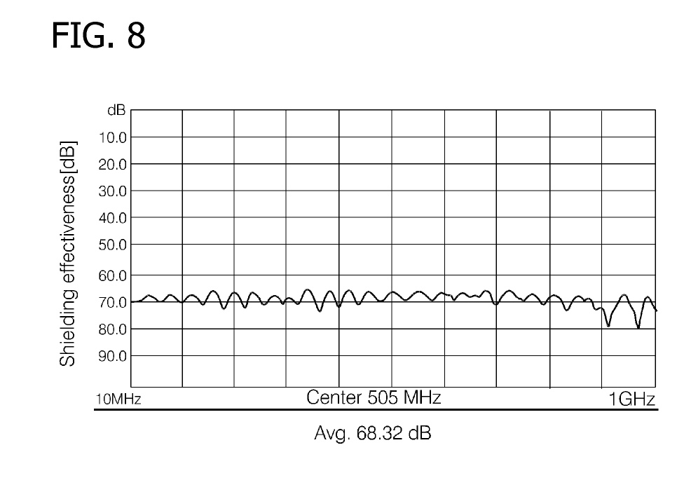

A first nickel plated layer was formed by plating a polyester material having a thickness of 100 μm with nickel and a copper plated layer acquired by plating the surface thereof with copper was formed. In addition, a second nickel plated layer was formed by secondarily plating the surface of the copper plated layer again with nickel to form the electromagnetic wave shielding layer 120. The electronic passport case 100 was manufactured by using the electronic wave shielding layer 120 and the electromagnetic wave shielding effectiveness and skimming prevention rate for the electronic passport case 100 were measured. A graph of a measurement result of the electromagnetic wave shielding effectiveness therefor was shown in FIG. 8.

### Example 4

The electronic passport case 100 was manufactured similarly to Example 3, but the electronic passport case 100 further including a gold plated layer acquired by plating the surface of the second nickel plated layer of the electromagnetic wave shielding layer 120 according to Example 3 with gold was manufactured.

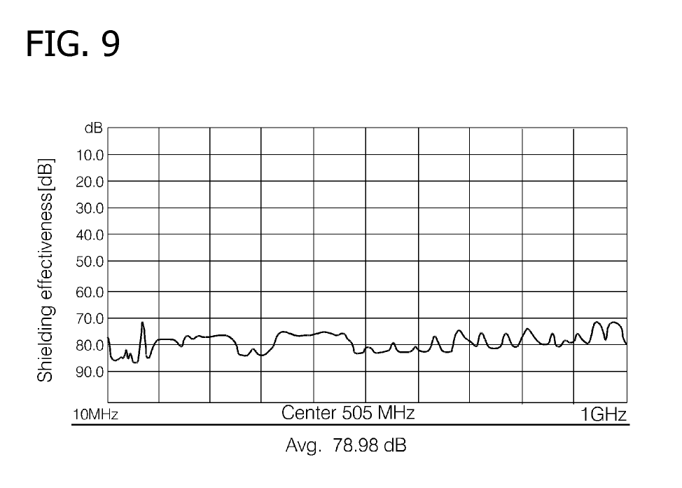

Thereafter, the electromagnetic wave shielding effectiveness and skimming prevention rate for the electronic passport case 100 were measured. A graph of a measurement result of the electromagnetic wave shielding effectiveness therefor was shown in FIG. 9.

### Example 5

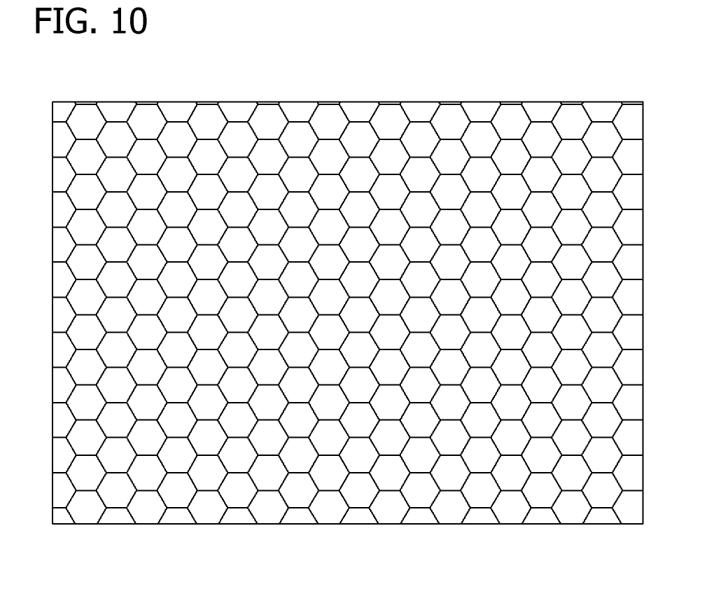

The electromagnetic wave shielding layer 120 as shown in FIG. 10 was formed by printing a hexagonal pattern on a polyethylene terephthalate film having a thickness of 50 μm with a conductive ink containing a silver powder, which has a thickness of 10 μm, a line width of 0.2 mm, and a line interval of 1.3 mm, and the electronic passport case 100 was manufactured by using the same.

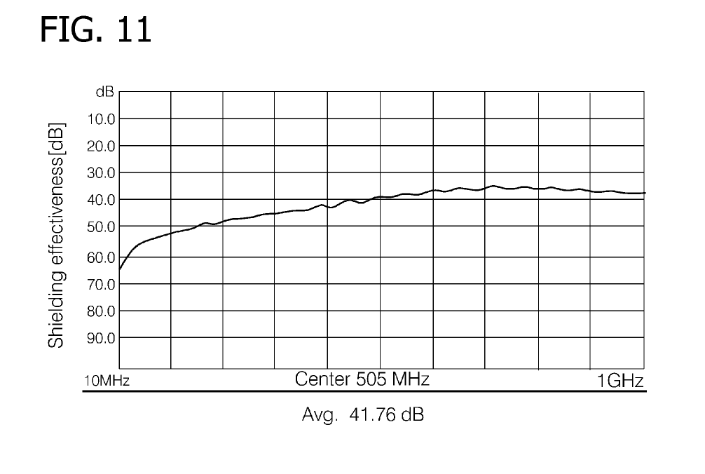

Thereafter, the electromagnetic wave shielding effectiveness and skimming prevention rate for the manufactured electronic passport case 100 were measured. A graph of a measurement result of the electromagnetic wave shielding effectiveness therefor was shown in FIG. 11.

Table 1 shown below adjusts and shows the measurement result of the electromagnetic wave shielding performance and skimming prevention performance for the electronic passport case 100 according to Examples 1 to 5.

TABLE 1

| | Kind of | Electromagnetic | Skimming |
|---|---|---|---|
| | electromagnetic | wave shielding | prevention |
| | wave shielding | effectiveness | effect |
| Classification | layer | (dB) | (%) |
| Example 1 | Metallic foil (Al) | 74 | 99.980 |
| Example 2 | Metallic foil (Cu) | 77 | 99.986 |
| Example 3 | Conductive material | | |
| | (Ni + Cu + Ni | 68 | 99.960 |
| | plated) | | |
| Example 4 | Conductive material | | |
| | (Ni + Cu + Ni + | 78 | 99.987 |
| | Gold plated) | | |
| Example 5 | Conductive ink | 41 | 99.108 |
| | printed sheet | | |

As shown in Table 1, the electromagnetic wave shielding effectiveness and skimming prevention rate were, on the whole, high with respect to Examples 1 to 5, and particularly, the electromagnetic wave shielding effectiveness and skimming prevention rate were the highest in Example 4.

### Example 6

The magnetic body 130 was formed in a sheet shape having a thickness of 0.2 mm by mixing a silicon resin with a ferrite powder and thereafter, the magnetic body 130 was combined with the electromagnetic wave shielding layer 120 according to Example 4 to manufacture the electronic passport case 100.

### Example 7

The electronic passport case 100 was manufactured in the same method as Example 6, but the electronic passport case 100 was manufactured by mixing a sendust (Fe—Si—Al) flake magnetic powder with the silicon resin instead of the ferrite powder.

### Example 8

The electronic passport case 100 was manufactured in the same method as Example 6, but the electronic passport case 100 was manufactured by mixing a permalloy (Fe—Ni) flake magnetic powder with the silicon resin instead of the ferrite powder.

### Example 9

The electronic passport case 100 was manufactured in the same method as Example 6, but the electronic passport case 100 was manufactured by mixing a Fe—Si—Cr based flake magnetic powder with the silicon resin instead of the ferrite powder.

The magnetic body 130 was placed in a part where the electronic chip 20 was positioned in the state where the magnetic body 130 of the electronic passport case 100 according to Examples 6 to 9 was placed between the electronic chip 20 of the electronic passport 10 and the electromagnetic wave shielding layer 120, and thereafter, the recognition rate of the electronic passport 10 was measured by using a radio-frequency identification reader recognizing the electronic chip 20 of the electronic passport 10. In regards to the recognition rate of the electronic passport 10, a wireless recognition distance of the electronic passport 10 was measured and it was determined that the recognition rate was higher when the recognition distance was longer.

Meanwhile, as a comparative example thereof, the wireless recognition distance was measured in the same method as above by covering one side of the electronic passport 10 with the electronic passport case 100 according to Example 4, which does not include the magnetic body 130. The result thereof was shown in Table 2.

TABLE 2

| | | Thickness of | |
|---|---|---|---|
| | | magnetic | Recognition |
| | Kind of magnetic | body sheet | distance |
| Classification | powder | (mm) | (mm) |
| Example 6 | Ferrite | 0.2 | 25 |
| Example 7 | Sendust (Fe—Si—Al) | 0.2 | 55 |
| Example 8 | Permalloy (Fe—Ni) | 0.2 | 45 |
| Example 9 | Fe—Si—Cr alloy | 0.2 | 40 |
| Comparative Example | — | — | 0 |
| (Example 4) | | | |

As shown in Table 2, the electronic passport case 100 including the magnetic body 130 has the higher recognition rate, and particularly, it can be seen that the recognition rate of the electronic passport 10 in the electronic passport case 100 manufactured according to Example 7 is the highest.

The spirit of the present invention has just been exemplified. It will be appreciated by those skilled in the art that various modifications, changes, and substitutions can be made without departing from the essential characteristics of the present invention. Accordingly, the exemplary embodiments disclosed in the present invention and the accompanying drawings are used not to limit but to describe the spirit of the present invention. The scope of the present invention is not limited only to the embodiments and the accompanying drawings. The protection scope of the present invention must be analyzed by the appended claims and it should be analyzed that all spirits within a scope equivalent thereto are included in the appended claims of the present invention.

1. An electronic passport case for preventing a leakage of information and improving recognition rate, the case comprising:
an electromagnetic wave shielding layer formed to cover an electronic passport and preventing an electronic wave from reaching an electronic chip incorporated in the electronic passport; and
a magnetic body provided between the electromagnetic wave shielding layer and the electronic chip and made of a material having magnetism,
wherein the electromagnetic wave shielding layer and the magnetic body are formed at a part where the electronic chip is positioned with a predetermined size to cover the electronic chip.

2. The case of claim 1, wherein the electromagnetic wave shielding layer is formed by a metallic foil reflecting the electromagnetic wave.

3. The case of claim 1, wherein the electromagnetic wave shielding layer is formed by a material plated with metal reflecting the electromagnetic wave.

4. The case of claim 1, wherein the electromagnetic wave shielding layer includes a sheet printed with a conductive ink.

5. The case of claim 1, wherein the magnetic body is formed in a sheet shape by mixing a magnetic powder with a polymer resin.

6. The case of claim 4, wherein the conductive ink is printed on a film in a polygonal shape.

7. The case of claim 5, wherein the magnetic body is formed by mixing any one or two or more of ferrite, sendust, permalloy, and Fe—Si—Cr based magnetic powders with any one polymer resin selected from silicon, urethane, and chlorinated polyethylene and in a sheet shape having a thickness in the range of 0.05 to 0.5 mm.

8. The case of claim 5, wherein the magnetic body includes a halogen free resin formed by sequentially adding and mixing polyolefin based elastomer and the sendust power and a deoxidant and a surface modifier.

9. The case of claim 1, wherein the electronic passport case further includes a spacer layer forming a spacing distance between the electronic chip and the magnetic at between the electronic chip and the magnetic body.

10. The case of claim 3, wherein the metal plated material is formed by sequentially laminating a first nickel plated layer, a copper plated layer, and a second nickel plated layer on the surface of a fiber material having a thickness in the range of 50 to 200 μm.

11. The case of claim 4, wherein the sheet printed with the conductive ink is formed by printing a hexagonal pattern having a thickness in the range of 5 to 30 μm, a line width in the range of 0.05 to 0.3 μm, and a line interval in the range of 0.5 to 2.0 μm on a polymer film having a thickness in the range of 20 to 200 μm by using a conductive ink including a silver (Ag) powder.

12. The case of claim 1, wherein the electromagnetic wave shielding layer and the magnetic body are coupled with each other through heat fusion.
